(19) United States
(12) Patent Application Publication
(10) Pub. No.: US 2025/0293424 A1
(43) Pub. Date: Sep. 18, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien CHIU, Taichung City (TW); Ko-Wei CHANG, Taichung City (TW); Chia-Chen CHIAO, Taichung City (TW); Chien-Cheng LIN, Taichung City (TW); Chun-Sheng CHANG, Taichung City (TW); Wen-Jung TSAI, Taichung City (TW)

(73) Assignee: SILICONWARE PRECISION INDUSTRIES CO., LTD., Taichung City (TW)

(21) Appl. No.: 18/910,909

(22) Filed: Oct. 9, 2024

(30) Foreign Application Priority Data
Mar. 14, 2024 (TW) 113109519

(51) Int. Cl. H01Q 1/22; H01L 21/48; H01L 23/00; H01L 23/31; H01L 23/498; H01L 23/538; H01L 23/552; H01L 25/16; H01Q 9/04; H01Q 21/06

(52) U.S. Cl. CPC H01Q 1/2283; H01L 21/4853; H01L 23/49811; H01L 23/5385; H01L 24/16; H01L 24/32; H01L 24/73; H01L 25/162; H01Q 9/0407; H01Q 21/065; H01L 23/3107; H01L 23/552; H01L 2224/16227; H01L 2224/32225; H01L 2224/73253

(57) ABSTRACT

An electronic package is provided, which includes: a packaging module having a first side, a second side opposite to the first side, and a first electronic element provided on the first side; an antenna module having a first surface and a second surface opposite to the first surface, wherein the first surface of the antenna module is coupled to the second side of the packaging module via a plurality of conductive elements; and a second electronic element disposed between the second side of the packaging module and the first surface of the antenna module. Also provided is a method of manufacturing the electronic package.

### BACKGROUND

### 1. Technical Field

The present disclosure relates to an electronic package and the manufacturing method thereof, and more particularly, to an electronic package having an antenna structure and manufacturing method thereof.

### 2. Description of Related Art

Nowadays, wireless communication technology has been widely applied in various consumer electronic products (such as mobile phones, tablet computers, etc.) to facilitate the reception of transmission of various wireless signals. Meanwhile, in order to satisfy the portability and convenience of consumer electronic products, the manufacturing and design of wireless communication modules are developed towards the requirements of being light, thin, short, and compact. Among them, the patch antenna has characteristics of small volume, light weight, and easy manufacturing to be widely used in wireless communication modules of electronic products.

FIG. 1 is a schematic cross-sectional view of a conventional semiconductor package 1. The semiconductor package 1 includes a packaging module 1a and an antenna module 1b, and the packaging module 1a consisted of a substrate 10, a radio frequency chip 11, and a power amplifier chip 12. The substrate 10 has a first side 10a and a second side 10b opposite to the first side 10a, the radio frequency chip 11 and the power amplifier chip 12 are provided on the first side 10a of the substrate 10, and the antenna module 1b is disposed on the second side 10b of the substrate 10 via a plurality of conductive elements 13.

In the conventional semiconductor package 1, in order to cope with the rapid decay of the radio frequency signal, the radio frequency chip 11 and the power amplifier chip 12 must be both disposed on the first side 10a of the substrate 10 to enhance the signal strength. However, this design causes an increase of the layout area of the substrate 10, thereby increasing the volume of the semiconductor package 1, which is difficult for the semiconductor package 1 to meet the requirements of being light, thin, short, and compact.

Therefore, there is a need for a solution that addresses the aforementioned shortcomings in the prior art.

### SUMMARY

In view of the aforementioned shortcomings of the prior art, the present disclosure provides an electronic package, which comprises: a packaging module having a first side, a second side opposite to the first side, and a first electronic element provided on the first side of the packaging module; an antenna module having a first surface and a second surface opposite to the first surface, wherein the first surface of the antenna module is coupled to the second side of the packaging module via a plurality of conductive elements; and a second electronic element disposed between the second side of the packaging module and the first surface of the antenna module.

In the aforementioned electronic package, the first electronic element is a radio frequency chip, and the second electronic element is a power amplifier chip.

In the aforementioned electronic package, the second electronic element is provided on the first surface of the antenna module in a flip-chip manner, and bonded to the second side of the packaging module via an adhesive layer.

In the aforementioned electronic package, the second electronic element is provided on the second side of the packaging module in a flip-chip manner, and bonded to the first surface of the antenna module via an adhesive layer.

In the aforementioned electronic package, an encapsulation layer is further formed between the second side of the packaging module and the first surface of the antenna module to encapsulate the second electronic element and the plurality of conductive elements.

In the aforementioned electronic package, the plurality of conductive elements are solder material or copper core balls.

In the aforementioned electronic package, the packaging module further has a connecting element disposed on the first side of the antenna module.

In the aforementioned electronic package, the antenna module further has a connecting element disposed on the first surface of the antenna module.

In the aforementioned electronic package, the second electronic element is a power amplifier chip having conductive silicon vias.

In the aforementioned electronic package, the antenna module comprises a plurality of antenna structures arranged in an array on the second surface.

The present disclosure further provides a method of manufacturing an electronic package, which comprises: providing a packaging module and an antenna module, wherein the packaging module has a first side, a second side opposite to the first side, and a first electronic element provided on the first side of the packaging module, and the antenna module has a first surface and a second surface opposite to the first surface; providing a second electronic element on the second side of the packaging module or on the first surface of the antenna module; and coupling the first surface of the antenna module to the second side of the packaging module via a plurality of conductive elements, allowing the second electronic element to be disposed between the second side of the packaging module and the first surface of the antenna module.

In the aforementioned the manufacturing method of the electronic package, the first electronic element is a radio frequency chip, and the second electronic element is a power amplifier chip.

In the aforementioned the manufacturing method of the electronic package, the second electronic element is provided on the first surface of the antenna module in a flip-chip manner, and bonded to the second side of the packaging module via an adhesive layer.

In the aforementioned the manufacturing method of the electronic package, the second electronic element is provided on the second side of the packaging module in a flip-chip manner, and bonded to the first surface of the antenna module via an adhesive layer.

In the aforementioned the manufacturing method of the electronic package, an encapsulation layer is further formed between the second side of the packaging module and the first surface of the antenna module to encapsulate the second electronic element and the plurality of conductive elements.

In the aforementioned the manufacturing method of the electronic package, the plurality of conductive elements are solder material or copper core balls.

In the aforementioned the manufacturing method of the electronic package, the packaging module further comprises a connecting element provided on the first side.

In the aforementioned the manufacturing method of the electronic package, the antenna module has a connecting element provided on the first surface.

In the aforementioned the manufacturing method of the electronic package, the second electronic element is a power amplifier chip having conductive silicon vias.

In the aforementioned the manufacturing method of the electronic package, the antenna module comprises a plurality of antenna structures arranged in an array on the second surface.

As can be understood from the above, in the electronic package of the present disclosure, a power amplifier chip is provided between an antenna module and a packaging module, rather than on a surface of the packaging module where the radio frequency chip is located, thus it can effectively reduce the required layout area of the packaging module and the overall volume of the electronic package, thereby the electronic package can meet the requirements of being light, thin, short, and compact. Besides, the power amplifier chip can be adhered to the antenna module and the packaging module at the same time which not only improves the signal performance, but also enhances the strength between the antenna module and the packaging module.

### BRIEF DESCRIPTION OF THE DRAWINGS

FIG. 1 is a schematic cross-sectional view of a conventional semiconductor package 1.

FIG. 2A to FIG. 2E are schematic cross-sectional views of a manufacturing method of an electronic package of the present disclosure.

FIG. 3A is a schematic cross-sectional view of another aspect of FIG. 2D.

FIG. 3B is a schematic cross-sectional view of another aspect of FIG. 2E.

FIG. 4 is a schematic cross-sectional view of another embodiment of an electronic package of the present disclosure.

FIG. 5 is a schematic cross-sectional view of another embodiment of an electronic package of the present disclosure.

FIG. 6 is a schematic cross-sectional view of another embodiment of an electronic package of the present disclosure.

FIG. 7 is a schematic cross-sectional view of another embodiment of an electronic package of the present disclosure.

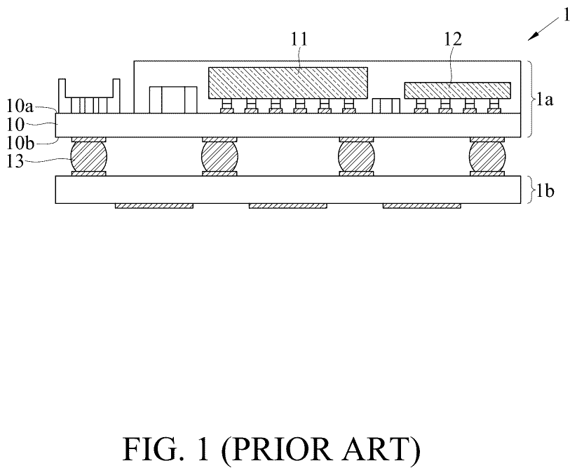

### DETAILED DESCRIPTION

The following describes the implementation of the present disclosure with examples. Those skilled in the art can easily understand the other advantages and effects of the present disclosure from the contents disclosed in this specification.

It should be understood that, the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modification of the structures, changes of the ratio relationships, or adjustment of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like are merely used for clear explanation rather than limiting the practicable scope of the present disclosure, and thus, alterations or adjustments of the relative relationships thereof without changes in the substantial technical content, should also to be regarded as within the scope in which the present disclosure can be implemented.

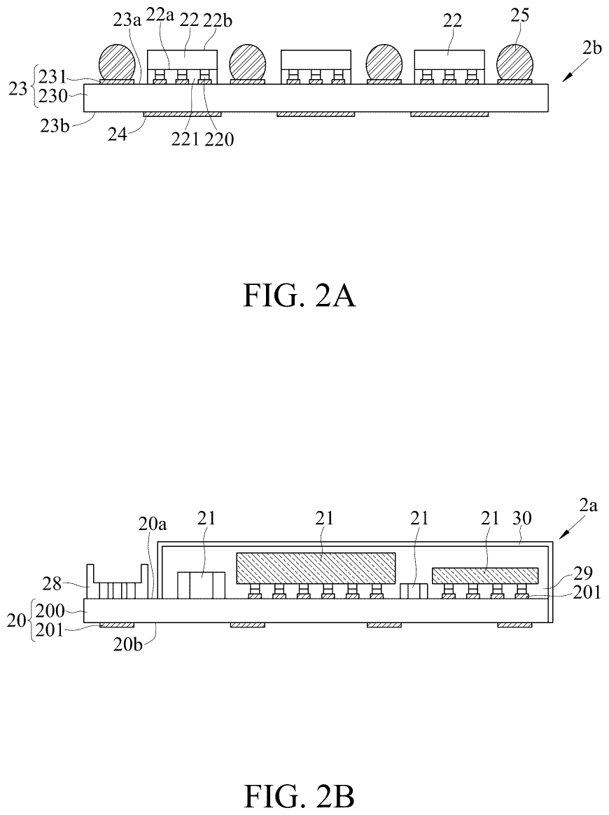

FIG. 2A to FIG. 2E are schematic cross-sectional views of a manufacturing method of an electronic package 2 of the present disclosure.

As shown in FIG. 2A, an antenna module 2b, a plurality of conductive elements 25 and a plurality of second electronic elements 22 on the antenna module 2b are provided.

The antenna module 2b has a board body 23 and a plurality of antenna structures 24. The board body 23 has a first surface 23a, a second surface 23b opposite to the first surface 23a, a dielectric material 230 and, a wiring layer 231, allowing the board body 23 to be a package substrate having a core layer and a circuit structure, or be in a coreless circuit structure form, but the present disclosure is not limited to as such. The plurality of antenna structures 24 are arranged in an array on the second surface 23b of the board body 23. For instance, each of the antenna structures 24 may have a patch antenna with a multi-layer circuit coupling, and may be a single band antenna design or a multiple bands antenna design with at least two bandwidths, allowing the second surface 23b of the board body 23 to be served as an antenna signal transmitting and receiving surface.

In an embodiment, the wiring layer 231 is made of copper, and the dielectric material 230 is, for example, polybenzoxazole (PBO), polyimide (PI), or prepreg (PP), etc.

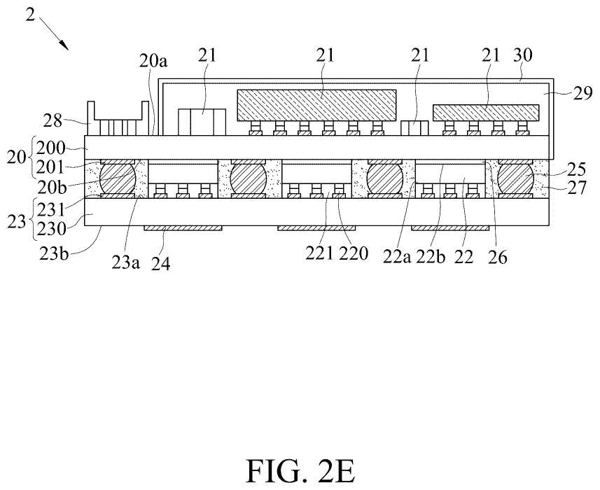

The plurality of conductive elements 25 are provided on the first surface 23a of the board body 23, and are electrically connected to the wiring layer 231. For instance, the plurality of conductive elements 25 can be spherical or columnar solder material, but the present disclosure is not limited to as such. In other embodiments, as shown in FIG. 4, the conductive element 25 can also be a Cu core ball, but the present disclosure is not limited to as such.

The second electronic element 22 has an active surface 22a and an inactive surface 22b opposite to the active surface 22a, and the active surface 22a of the second electronic element 22 is provided on the first surface 23a of the antenna module 2b via a plurality of conductive bumps 220, so as for the second electronic element 22 to be electrically connected to the wiring layer 231 of the antenna module 2b. The second electronic element 22 is, for example, a semiconductor chip, and specifically a power amplifier IC. In addition, an underfill 221 is filled between the second electronic element 22 and the antenna module 2b to encapsulate the plurality of conductive bumps 220.

In an embodiment, the second electronic element 22 is provided on the first surface 23a of the antenna module 2b in a flip-chip manner. The second electronic element 22 can also be electrically connected to the wiring layer 231 of the antenna module 2b via wire bonding, direct contact, or other appropriate methods, but the present disclosure is not limited to as such.

Furthermore, a plurality of conductive elements 25 and a plurality of electronic elements 22 are disposed on the antenna module 2b first, and after the underfill 221 is filled between the plurality of electronic elements 22 and the antenna module 2b, a singulation process is carried out to obtain the structure as shown in FIG. 2A.

As shown in FIG. 2B, a packaging module 2a is provided and is a system in package (SiP) structure comprising a substrate 20, a first electronic element 21 and a connecting element 28 provided on the substrate 20, and a packaging layer 29 provided on the substrate 20 and encapsulating the first electronic element 21.

The substrate 20 has a first side 20a, a second side 20b opposite to the first side 20a, a dielectric material 200, and a plurality of wiring layers 201, such as fan out redistribution layer (RDL), formed on the dielectric material 200. The substrate 20 may be a package substrate with a core layer or a coreless package substrate.

The first electronic element 21 is provided on the first side 20a of the substrate 20, and electrically connected to the wiring layer 201. The first electronic element 21 may be, for example, an active element, a passive element, or a combination thereof. The active element is, for example, a semiconductor chip, and specifically a radio frequency chip (RFIC), and is provided on the first side 20a of the substrate 20 in a flip-chip manner, but the present disclosure is not limited to as such. The active element can also be electrically connected to the wiring layer 201 via wire bonding, direct contact, or other appropriate methods. The passive element is, for example, a resistor, a capacitor, or an inductor.

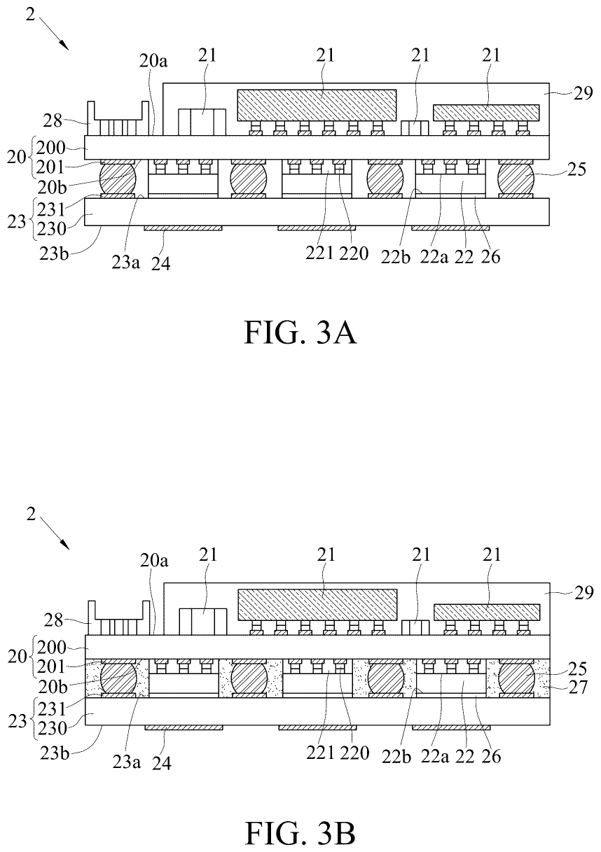

The connecting element 28 is provided on the first side 20a of the substrate 20 and exposed from the packaging layer 29. The connecting element 28 is also spaced apart from the first electronic element 21. The connecting element 28 may be a connector. In other embodiments, as shown in FIG. 5, the connecting element 28 can also be provided on the antenna module 2b, specifically provided on the first surface 23a of the board 23, but the present disclosure is not limited to as such.

The packaging layer 29 is formed on the first side 20a of the substrate 20 for encapsulating the first electronic element 21. In an embodiment, the packaging layer 29 can be an insulating material, such as polyimide (PI), dry film, or an encapsulant, such as epoxy or a molding compound, but the present disclosure is not limited to as such.

In an embodiment, a shielding structure 30 can be formed on the packaging layer 29 according to requirements, allowing the first element 21 to be shielded by the shielding structure 30. By such a design, the first electronic element 21 is not subject to external electromagnetic interference. Further, the layout area of the shielding structure 30 can be selectively extended to the side of the substrate 20 according to requirements.

In an embodiment, the manufacturing processes of the antenna module 2b as shown in FIG. 2A and of the packaging module 2a as shown in FIG. 2B are without sequential. They can be manufactured in different production lines at the same time, or they can be manufactured in the same production line one after another.

As shown in FIG. 2C, an adhesive layer 26 is dispsoed on the second side 20b of the substrate 20.

In an embodiment, the adhesive layer 26 can be a molding compound such as epoxy, insulating glue, conductive glue, or other appropriate materials, etc.

As shown in FIG. 2D, the antenna module 2b is provided on the packaging module 2a, allowing the second electronic element 22 to be disposed between the packaging module 2a and the antenna module 2b.

In an embodiment, the first surface 23a of the board body 23 is coupled to the second side 20b of the substrate 20 via a plurality of conductive elements 25, allowing the inactive surface 22b of the second electronic element 22 to be bonded to the second side 20b of the substrate 20 via the adhesive layer 26, and the plurality of conductive element 25 are coupled to and electrically connected to the wiring layer 201. As a result, the electronic package 2 of the present disclosure is thus obtained.

In the subsequent processes, as shown in FIG. 2E, an encapsulation layer 27 can be formed between the second side 20b of the substrate 20 and the first surface 23a of the board body 23 to encapsulate the second electronic element 22 and the conductive element 25. The encapsulation layer 27 can be, for example, an insulating material, such as polyimide (PI), dry film, or an encapsulant, such as epoxy or a molding compound, etc.

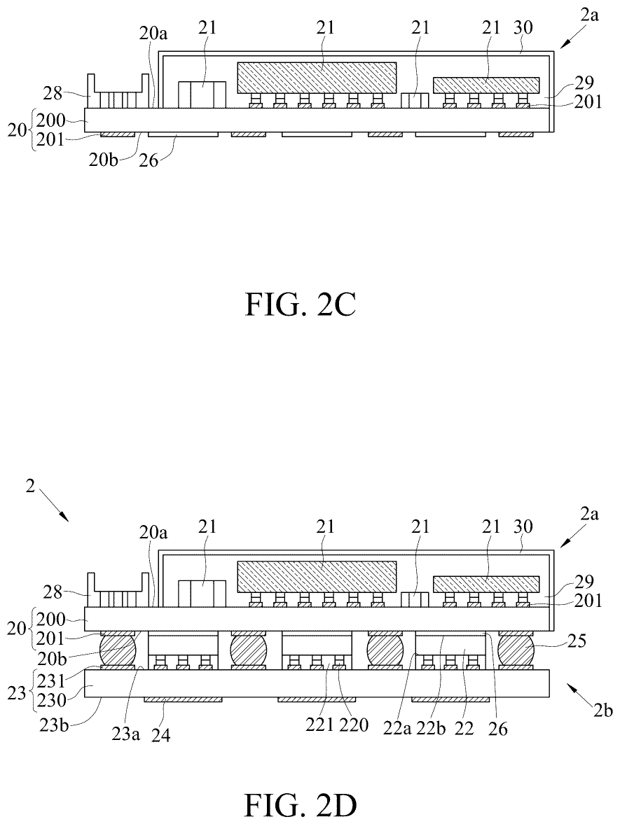

In the above embodiment, the active surface 22a of the second electronic element 22 is coupled to the first surface 23a of the board body 23 in a flip-chip manner, and then the adhesive layer 26 is bonded to the inactive surface 22b of the second electronic element 22 and the second side 20b of the substrate 20, but the present disclosure is not limited to as such. As shown in FIG. 3A, the active surface 22a of the second electronic element 22 can also be coupled to the second side 20b of the substrate 20 in a flip-chip manner and electrically connected to the wiring layer 201, and then the adhesive layer 26 is bonded to the inactive surface 22b of the second electronic element 22 and the first surface 23a of the board body 23. Afterwards, as shown in FIG. 3B, the encapsulation layer 27 can be formed between the second side 20b of the substrate 20 and the first surface 23a of the board body 23 to encapsulate the second electronic element 22 and the conductive element 25.

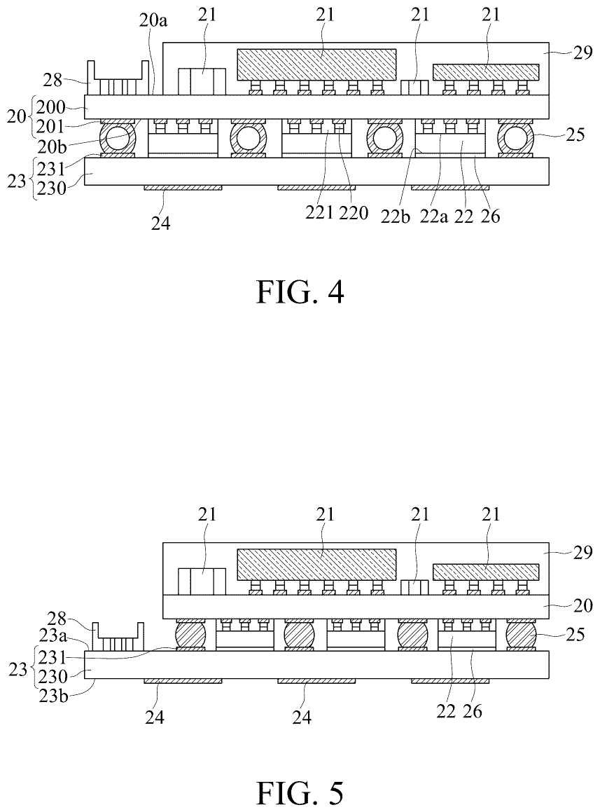

Moreover, as shown in FIG. 6, a grinding process can be performed to the inactive surface 22b of the second electronic element 22 to reduce the thickness of the second electronic element 22, and the conductive element 25 with small dimension can be used to increase the number of contacts, so as to reduce a distance H between the first surface 23a of the board body 23 and the second side 20b of the substrate 20. Therefore, the overall thickness of the electronic package 2 is reduced.

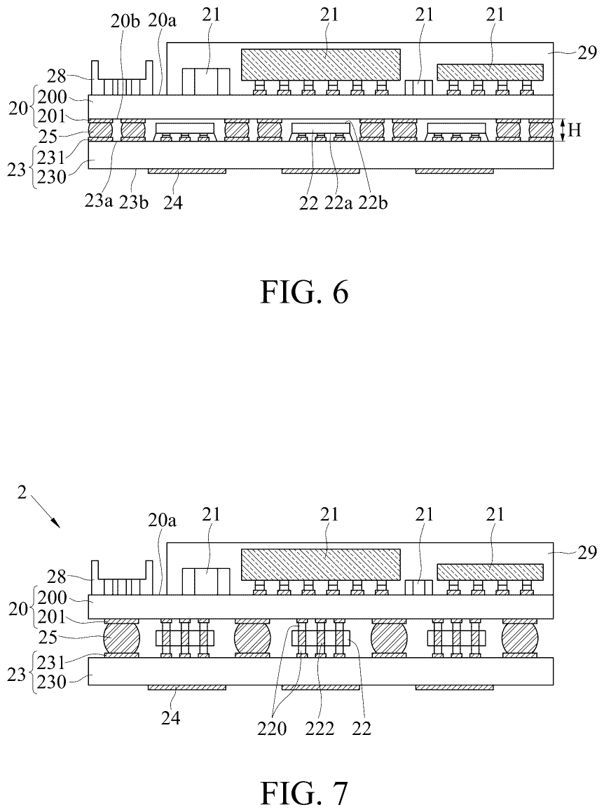

Additionally, in order to improve the performance of the electronic package 2, as shown in FIG. 7, the second electronic element 22 can be a power amplifier chip having a plurality of conductive through-silicon vias (TSV) 222, the two opposite surfaces of the second electronic element 22 are penetrated by the plurality of conductive through-silicon vias 222 simultaneously, and the plurality of conductive through-silicon vias 222 are electrically connected to the wiring layer 201 of the substrate 20 and the wiring layer 231 of the board 23 respectively via conductive bumps 220.

In view of the above, in the electronic package of the present disclosure, a power amplifier chip is provided between an antenna module and a packaging module, rather than on the surface of the packaging module where the radio frequency chip is located, thus it can effectively reduce the required layout area of the packaging module and the overall volume of the electronic package, thereby the electronic package can meet the requirements of being light, thin, short, and compact. Besides, the power amplifier chip can be adhered to the antenna module and the packaging module at the same time, which not only improves the signal performance, but also enhances the strength between the antenna module and the packaging module.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a packaging module having a first side, a second side opposite to the first side, and a first electronic element, wherein the first electronic element is provided on the first side;
an antenna module having a first surface and a second surface opposite to the first surface, wherein the first surface of the antenna module is coupled to the second side of the packaging module via a plurality of conductive elements; and
a second electronic element disposed between the second side of the packaging module and the first surface of the antenna module.

2. The electronic package of claim 1, wherein the first electronic element is a radio frequency chip, and the second electronic element is a power amplifier chip.

3. The electronic package of claim 1, wherein the second electronic element is provided on the first surface of the antenna module in a flip-chip manner, and bonded to the second side of the packaging module via an adhesive layer.

4. The electronic package of claim 1, wherein the second electronic element is provided on the second side of the packaging module in a flip-chip manner, and bonded to the first surface of the antenna module via an adhesive layer.

5. The electronic package of claim 1, further comprising an encapsulation layer formed between the second side of the packaging module and the first surface of the antenna module to encapsulate the second electronic element and the plurality of conductive elements.

6. The electronic package of claim 1, wherein the plurality of conductive elements are solder material or copper core balls.

7. The electronic package of claim 1, wherein the packaging module further comprises a connecting element provided on the first side.

8. The electronic package of claim 1, wherein the antenna module comprises a connecting element provided on the first surface.

9. The electronic package of claim 1, wherein the second electronic element is a power amplifier chip having conductive silicon vias.

10. The electronic package of claim 1, wherein the antenna module comprises a plurality of antenna structures arranged in an array on the second surface of the antenna module.

11. A method of manufacturing an electronic package, comprising:
providing a packaging module and an antenna module, wherein the packaging module has a first side, a second side opposite to the first side, and a first electronic element provided on the first side, and the antenna module has a first surface and a second surface opposite to the first surface;
providing a second electronic element on the second side of the packaging module or on the first surface of the antenna module; and
coupling the first surface of the antenna module to the second side of the packaging module via a plurality of conductive elements, such that the second electronic element is disposed between the second side of the packaging module and the first surface of the antenna module.

12. The method of claim 11, wherein the first electronic element is a radio frequency chip, and the second electronic element is a power amplifier chip.

13. The method of claim 11, wherein the second electronic element is provided on the first surface of the antenna module in a flip-chip manner, and bonded to the second side of the packaging module via an adhesive layer.

14. The method of claim 11, wherein the second electronic element is provided on the second side of the packaging module in a flip-chip manner, and bonded to the first surface of the antenna module via an adhesive layer.

15. The method of claim 11, further comprising an encapsulation layer formed between the second side of the packaging module and the first surface of the antenna module to encapsulate the second electronic element and the plurality of conductive elements.

16. The method of claim 11, wherein the plurality of conductive elements are solder material or copper core balls.

17. The method of claim 11, wherein the packaging module further comprises a connecting element provided on the first side.

18. The method of claim 11, wherein the antenna module comprises a connecting element provided on the first surface.

19. The method of claim 11, wherein the second electronic element is a power amplifier chip having conductive silicon vias.

20. The method of claim 11, wherein the antenna module comprising a plurality of antenna structures arranged in an array on the second surface.
